(19) United States
(12) Patent Application Publication
(10) Pub. No.: US 2025/0006804 A1
(43) Pub. Date: Jan. 2, 2025

(54) SEMICONDUCTOR DEVICE INCLUDING AN ETCH STOP LAYER FOR CONTACT HOLE FORMATION

(71) Applicant: TEXAS INSTRUMENTS INCORPORATED, Dallas, TX (US)

(72) Inventors: Manoj Mehrotra, Plano, TX (US); Yu-Lun Lin, Plano, TX (US)

(21) Appl. No.: 18/344,570

(22) Filed: Jun. 29, 2023

(51) Int. Cl. H01L 29/417; H01L 21/311; H01L 29/08; H01L 29/78

(52) U.S. Cl. CPC H01L 29/41725; H01L 21/31111; H01L 29/0847; H01L 29/7843

(57) ABSTRACT

A semiconductor device including a contact plug formed in a contact hole using a multi-stage contact etch process. The semiconductor device comprises a source/drain region over a semiconductor substrate, an oxide layer extension extending from the source/drain region toward a gate dielectric layer, and a contact plug extending through a dielectric layer over the source/drain region, the contact plug extending through a first etch stop layer and a second etch stop layer to a horizontal remaining portion of the oxide layer extension.

### FIELD OF THE DISCLOSURE

Disclosed implementations relate generally to the field of semiconductor devices and fabrication. More particularly, but not exclusively, the disclosed implementations relate to a semiconductor device including an etch stop layer for contact hole formation.

### BACKGROUND

Obtaining a reliable contact etch process remains a challenging aspect in fabricating VLSI circuits. Process control of this step is impeded by at least three sources of difficulty: (1) the plasma etch rate in small openings is inherently uncertain; (2) the contact etch must cut through various dielectric stack thicknesses across the wafer; and (3) normal endpoint detection techniques are inaccurate in a contact etch setting, so an extra overetch must be added to an endpoint estimated (however imprecisely) by timing. For all these reasons, substantial overetch (e.g., etching for more than the time required to clear from a flat surface the dielectric stack thickness which overlies the contact hole location) is necessary to assure that the contact makes reliable electrical connection.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

In one example, a semiconductor device including a contact plug in a contact hole formed using a multi-stage contact etch process is disclosed. In an example arrangement, the semiconductor device comprises a source/drain region over a semiconductor substrate, an oxide layer extension extending from the source/drain region toward a gate dielectric layer, and a contact plug extending through a dielectric layer over the source/drain region, wherein the contact plug extends through a first etch stop layer (e.g., a nitride-based pre-metal dielectric (PMD) liner underlying an oxide-based PMD layer in a PMD stack) and a second etch stop layer to a horizontal remaining portion of the oxide layer extension. Depending on implementation, the second etch stop layer may comprise a conformal layer formed of a material selected from at least one of silicon carbide nitride (SiCN), silicon oxynitride (SiON) and silicon carbide (SiC), and may have a thickness of about 5 nm to 10 nm.

In another example, a semiconductor device is disclosed, wherein the semiconductor device comprises a substrate including a source region, a drain region and a channel region separating the source region and the drain region. The semiconductor device also includes a gate dielectric layer over the channel region, a gate structure over the gate dielectric layer, and a contact opening over the source region or the drain region, wherein the contact opening extends through an etch stop layer underlying a PMD stack comprising a PMD liner overlying the etch stop layer and a PMD layer overlying the PMD liner. In an example arrangement, the gate structure of the semiconductor device may be covered by a multi-layer vertical sidewall including an oxide layer, a portion of the etch stop layer at least partially covering the oxide layer, and a portion of the PMD liner at least partially covering the etch stop layer.

In another example, a method of fabricating a semiconductor device using a multi-stage contact etch process is disclosed. The method may comprise a first etch stage for forming a contact hole in a contact region of the semiconductor device, wherein an oxide layer of a PMD stack is etched to create a partially formed contact hole extending through the oxide layer and landing in a first etch stop layer forming part of the PMD stack. The method may comprise a second etch stage, wherein the first etch stop layer is etched to extend the partially formed contact hole to land in a second etch stop layer overlying a silicide area of the contact region, the silicide area abutting an oxide layer extension extending from a source/drain region toward a gate dielectric layer. The method may comprise a third etch stage wherein the second etch stop layer is etched to form a completed contact hole landing on the silicide area of the contact region and at least a portion of the oxide layer extension remaining unconsumed after the third etch stage.

### BRIEF DESCRIPTION OF THE DRAWINGS

Implementations of the present disclosure are illustrated by way of example, and not by way of limitation, in the Figures of the accompanying drawings. It should be noted that different references to “an” or “one” implementation in this disclosure are not necessarily to the same implementation, and such references may mean at least one. Further, when a particular feature, structure, or characteristic is described in connection with an implementation, it is submitted that it is within the knowledge of one skilled in the art to effect such feature, structure, or characteristic in connection with other implementations whether or not explicitly described.

The accompanying drawings are incorporated into and form a part of the specification to illustrate one or more example implementations of the present disclosure. Various advantages and features of the disclosure will be understood from the following Detailed Description taken in connection with the appended claims and with reference to the attached drawing Figures in which:

FIGS. 1A-1H depict cross-sectional views of a partially formed semiconductor device at various stages of fabrication wherein a contact hole may be formed using an etch stop layer according to some examples of the present disclosure; and

FIG. 2 is a flowchart of a method of fabricating a semiconductor device according to some examples of the present disclosure.

### DETAILED DESCRIPTION

Examples of the disclosure are described with reference to the attached Figures wherein like reference numerals are generally utilized to refer to like elements. The Figures are not drawn to scale and they are provided merely to illustrate examples. Numerous specific details, relationships, and methods are set forth below to provide an understanding of one or more examples. However, it should be understood that some examples may be practiced without such specific details. In other instances, well-known subsystems, components, structures and techniques have not been shown in detail in order not to obscure the understanding of the examples. Accordingly, it will be appreciated by one skilled in the art that the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. “Directly connected” may be used to convey that two or more physical features touch, or share an interface between each other.

Various disclosed methods and devices of the present disclosure may be beneficially applied to manufacturing electronic devices such as transistors or memory cells, especially where such devices are closely spaced on a semiconductor substrate. While such embodiments may be expected to reduce manufacturing defects that could otherwise reduce reliability or electrical performance, no particular result is a requirement of the present disclosure unless explicitly recited in a particular claim.

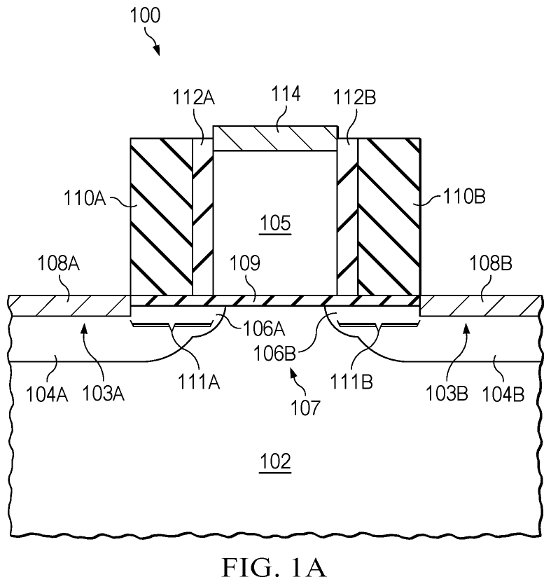

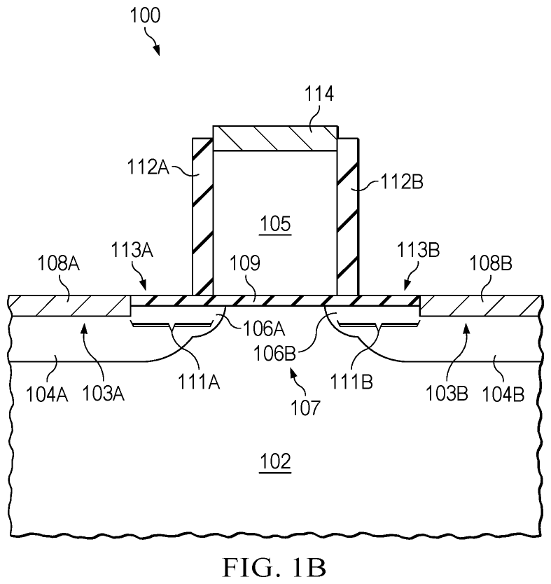

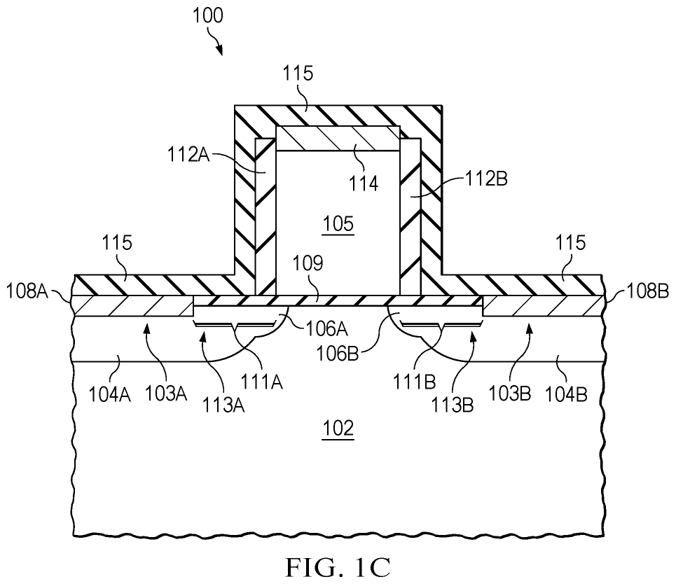

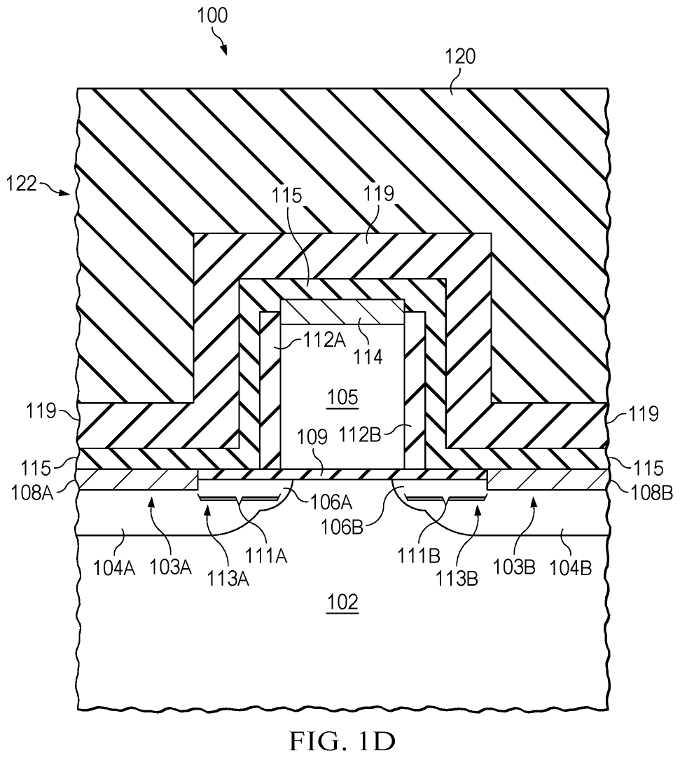

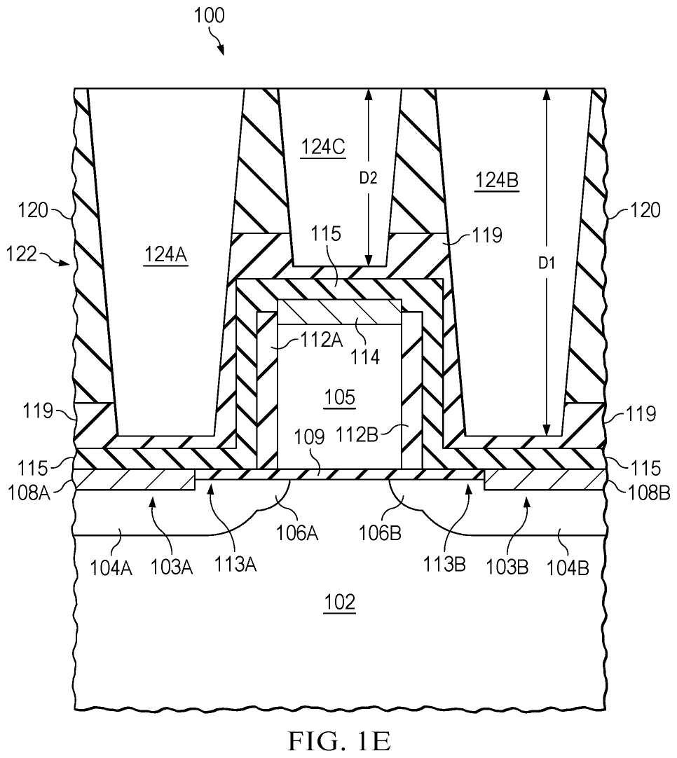

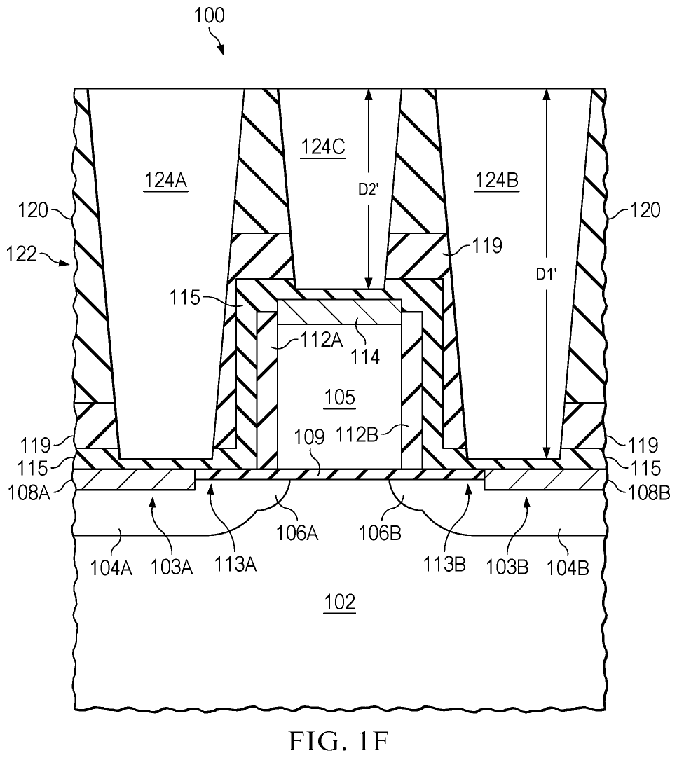

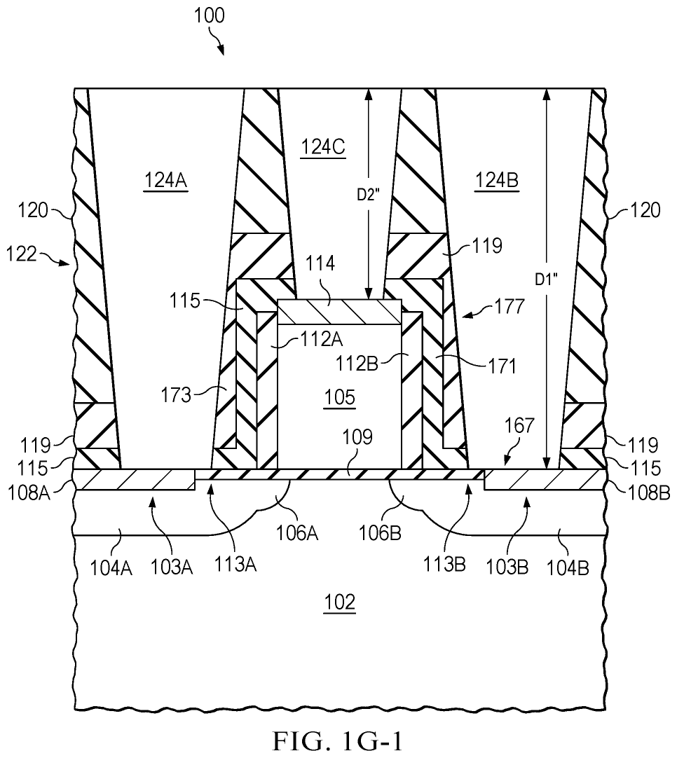

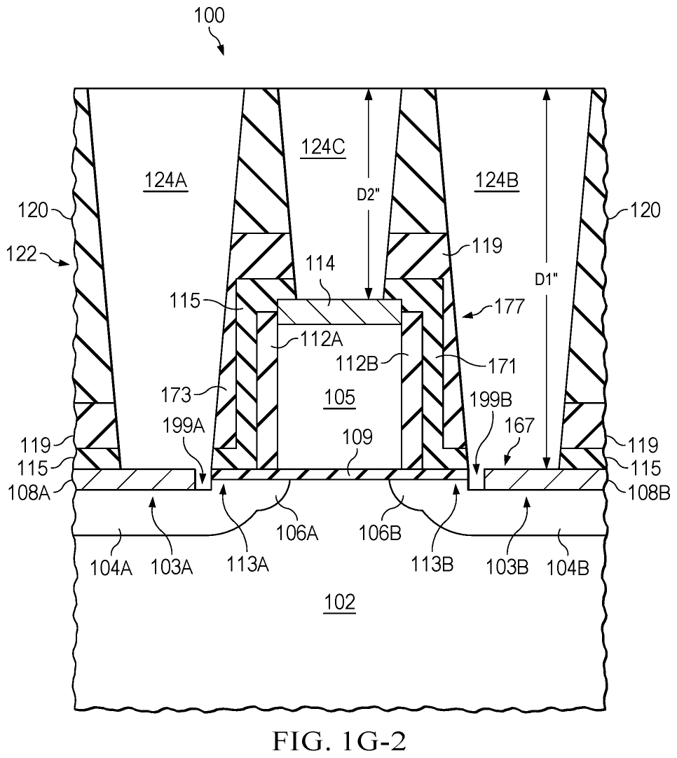

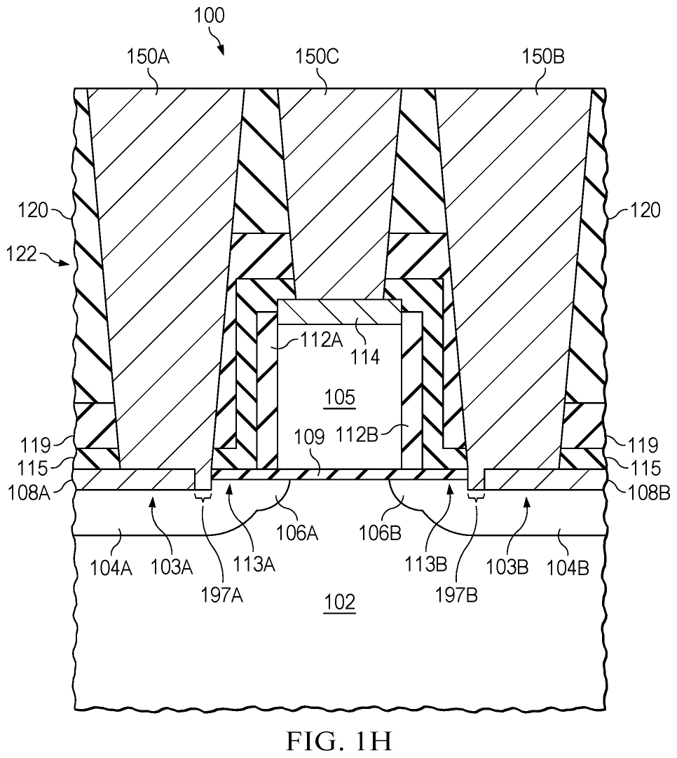

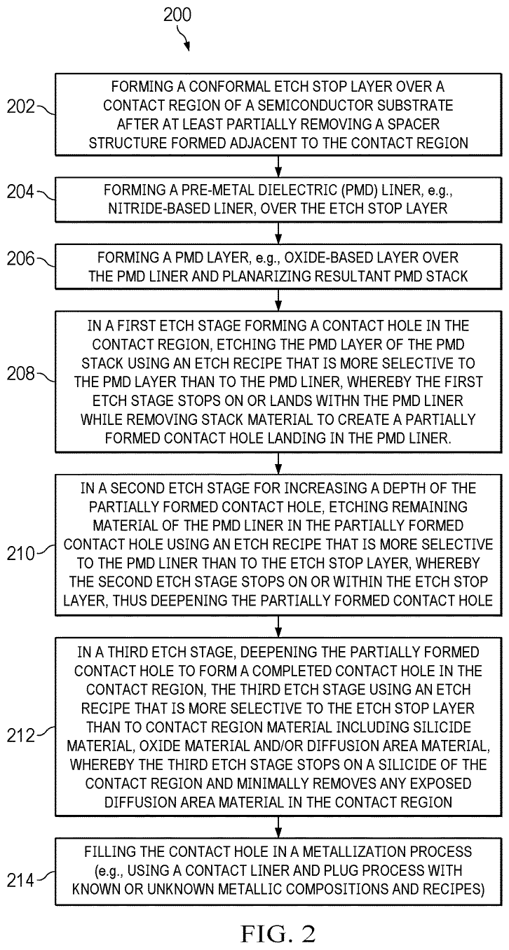

Referring to the drawing Figures, FIGS. 1A-1H depict cross-sectional views of a partially formed semiconductor device at various stages of fabrication where a contact hole may be formed using an etch stop layer in a multi-stage contact etch process according to some examples of the present disclosure. FIG. 2 is a flowchart of a fabrication method 200 that summarizes various steps, wherein at least a portion of the steps may roughly correspond to the fabrication stages shown in FIGS. 1A-1H. Taking reference to FIGS. 1A-1H and 2 together, a contact etch process flow will be set forth in accordance with a representative implementation relating to forming a contact hole for a semiconductor device 100, e.g., a MOSFET device, without limitation. As illustrated in FIG. 1A, example semiconductor device, or an integrated circuit (IC), 100 is depicted at a fabrication stage after silicide formation, e.g., as part of a back end of line (BEOL) flow. A gate dielectric layer 109 of appropriate thickness and material composition may be formed over an active area 107, or channel region, of a substrate 102 that may comprise any suitable semiconductor material having appropriate doping. Depending on implementation, the gate dielectric layer 109 may comprise one or more sub-layers (not specifically shown in the Figures). In some examples, the gate dielectric layer 109 may comprise a stack including an oxide layer of about 1 nm to 2 nm deposited or formed over the active area 107 and a nitride layer of about 1.5 nm to 2.5 nm formed over the oxide layer, although other material compositions and/or layer thicknesses may be provided in other implementations. A conductive layer such as a doped polysilicon (“poly”) layer formed over the gate dielectric layer 109 may be patterned to form a poly gate structure 105, wherein at least a portion of the gate dielectric layer 109 may extend beyond the poly gate structure 105, e.g., as oxide extensions 111A, 111B that extend over diffusion regions formed in the substrate 102 and abutting respective silicide areas 108A/108B as will be set forth below.

Depending on the application and process node technology, the poly gate structure 105 may have a thickness ranging from about 50 nm to 150 nm, although other thicknesses may be used in additional and/or alternative implementations. In some arrangements, shallow source/drain extension (SDE) regions 106A, 106B may be formed in respective areas of the substrate 102 underlying the oxide extensions 111A, 111B, e.g., using the gate structure 105 as a mask, as known in the art. In some arrangements, one or more insulating structures covering vertical side surfaces of the gate structure 105 may be formed over the oxide extensions 111A/111B, wherein the insulating structures may comprise multiple layers of suitable materials and thicknesses. In an example, each vertical side surface of the gate structure 105 may be covered by a respective sidewall spacer 112A, 112B comprising an oxide of about 1 nm to 3 nm formed by gate poly oxidation and an oxide of about 5 nm to 10 nm that may be deposited, e.g., by chemical vapor deposition (CVD) using tetraethyl orthosilicate (TEOS) feedstock. Thereafter, a vertical nitride spacer 110A, 110B having a suitable thickness may be formed covering each oxide sidewall spacer 112A, 112B, respectively. In an example, a deposition process using gases such as dichlorosilane (DCS), hexachlorodisilane (HCD), ammonia (NH₃), etc., may be implemented for depositing a nitride layer, which may be etched to form the vertical spacers 110A, 110B having a thickness of about 15 nm to 30 nm.

Continuing to refer to FIG. 1A, moderately- or heavily-doped source/drain (S/D) regions 104A, 104B, which are typically deeper than SDE regions 106A, 106B, may be formed in the substrate 102 of the semiconductor device 100, wherein the spacers 110A, 110B may be used for blocking dopants from the SDE regions 106A, 106B, as known in the art. A silicidation process may be employed for forming a gate metal-silicide 114 over the gate structure 105 and S/D metal-silicides 108A, 108B over contact regions or junctions 103A, 103B disposed in the corresponding S/D regions 104A, 104B, respectively. Skilled artisans will recognize that example gate silicide 114 and S/D silicides 108A/B may be formed using a variety of metals (e.g. W, Cr or Ti) and silicidation loops depending on implementation, e.g., including self-aligned silicidation or “salicidation”, wherein the metal silicides 114, 108A/B operate as contact areas or means having low resistivity for electrically accessing the gate structure 105 and S/D regions 104A/104B, respectively.

In some arrangements, at least a portion of the spacers 110A, 110B may be removed or reduced prior to subsequent processing of the semiconductor device 100. In some arrangements, additional spacers may be formed as an optional implementation prior to doping S/D regions 104A, 104B, wherein the additional/optional spacers may also be removed (at least partially) using a suitable process, e.g., dry or wet etching. Accordingly, in some arrangements, the oxide extensions 111A, 111B extending under the previously formed spacers 110A, 110B may become at least partially exposed. By way of example, after the formation of various silicides, e.g., gate silicide 114, S/D silicides 108A/108B, and subsequent spacer removal (partial or otherwise), the semiconductor device 100 may be seen to include one or more exposed oxide zones or areas 113A, 113B, which comprise at least a portion of the oxide extensions 111A/111B, respectively, as depicted in FIG. 1B. Depending on implementation, the exposed oxide areas 113A/113B may extend to and abut the S/D silicides 108A/108B formed in the contact regions 103A, 103B, respectively, wherein the exposed oxide areas 113A, 113B are disposed over unsilicided areas of respective S/D regions 104A, 104B. From a reverse direction, the exposed oxide areas 113A/113B may be seen as extending from the respective S/D silicides 108A/108B toward the gate dielectric layer 109.

It should be appreciated that exposing oxide-covered unsilicided regions in a partially formed semiconductor device may engender various deleterious effects during subsequent processing, e.g., in contact hole formation and metallization. Because the exposed oxide regions are often formed proximate to the doped junctions of the device, a baseline contact (CT) etch process may punch through the exposed regions, thereby increasing the risk of excessive current leakage. A baseline CT process may also cause consumption or removal of the substrate material underlying the exposed oxide regions, e.g., doped silicon from the S/D regions and/or any extensions associated therewith, during an uncontrolled etching stage such as a contact liner overetch process, which can give rise to significant variation in transistor performance. Further, as there is an increased likelihood of forming overetch cavities in a contact region that may not be filled properly during contact metallization, the risk of contact voids that can negatively impact the device performance or reliability is also increased. Moreover, tighter critical dimensions (CDs) and related gate-to-contact design rules contemplated in advanced process nodes further exacerbate the foregoing concerns, especially where stack structures having multiple heights and aspect ratios are expected.

Examples herein recognize the aforementioned challenges and accordingly provide a more controlled multi-stage CT etch process that includes a more controlled final etch stop layer having a high etch selectivity relative to materials forming overlying layers in a pre-metal dielectric (PMD) stack (that may be formed before contact hole formation in a BEOL flow) as well as underlying exposed oxide material and the unsilicided substrate material of a semiconductor device. Whereas some examples are particularly advantageous in mitigating the risk of exposed unsilicided regions caused in a removable spacer process, it should be appreciated that the teachings herein may also be practiced in flows that do not necessarily expose unsilicided regions in order to improve contact overetch margins, e.g., to reduce the likelihood that a contact etch may punch through silicided regions as well as regions having thinner or nonuniform silicides. Further, although examples herein are set forth in the context of contact hole formation in FET devices so as to mitigate issues relating to, inter alia, the contact-to-gate spacing, the teachings of the present disclosure are not limited thereto and may be practiced with respect to any semiconductor device or structure requiring contacts to be made to the active regions in the substrate, whether or not unsilicided, e.g., contact holes formed relative to capacitors, diodes, resistors, etc., formed in ICs or as discrete devices. Although example arrangements set forth herein may therefore be expected to provide a range of various tangible improvements depending on application, no particular result is a requirement unless explicitly recited in a particular claim.

Turning to FIG. 1C, a conformal etch stop layer (ESL) 115 is be formed over the semiconductor device 100 after (at least partial) spacer removal, wherein ESL 115 may be operable as an additional and/or final etch stop layer in a multi-stage CT etch process that provides differential etch selectivity for facilitating better etch/overetch control. In some examples, the conformal ESL 115 may comprise silicon carbide nitride (SiCN), silicon carbide (SiC), silicon oxynitride (SiON), and/or other dielectric materials or combinations thereof that provide a different etch rate relative to the exposed oxide and underlying substrate material in the contact regions 103A, 103B as well as to one or more overlying PMD layers formed in a subsequent PMD stack formation stage. As will be set forth in detail further below, an example ESL 115 may be provided as a final etching stage in a three-stage CT etch process according to some implementations, wherein the ESL material is more resistant to removal by an etch recipe configured to remove an overlying layer, while the ESL material also being more readily removed than the underlying oxide/substrate silicon in an ESL etch stage endpointed to stop on a silicide area.

In an example implementation, ESL 115 may be provided as a thin layer, e.g., having a thickness of about 5 nm to 10 nm, which may be formed by a suitable deposition process, e.g., plasma enhanced chemical vapor deposition (PECVD) having processing temperatures around 200° C. to 400° C. and TEOS feedstock. In some examples, ESL 115 may be provided as a stressor film having a sufficient film stress (e.g., greater than 1 Gigapascal (GPa)) that is designed to not diminish or otherwise attenuate the stress/strain field properties of an overlying PMD layer, e.g., a PMD liner layer, which may be configured and/or required to condition the properties of the semiconductor device 100 at the channel surface such as, e.g., bandgap energy, dielectric constant, charge carrier mobility, etc., depending on the application and technology node. In some examples where the semiconductor device 100 is an NMOS transistor, ESL 115 may be operable as a tensile stressor. Analogously, where the semiconductor device 100 is a PMOS transistor, ESL 115 may be provided as a compressive stressor.

After forming ESL 115, a pre-metal dielectric (PMD) stack 122 containing one or more layers may be formed over the semiconductor device 100 as set forth in the fabrication stage of FIG. 1D and at blocks 204 and 206, e.g., using known or heretofore unknown techniques and process recipes depending on implementation and process technology node. In one arrangement, PMD stack 122 may comprise a PMD liner layer (PLL) 119 that may be formed over ESL 115 in a deposition process, e.g., PECVD having suitable parameters for depositing a nitride-based layer having a thickness of approximately 20 nm to 40 nm. Thereafter, an oxide-based PMD layer 120 may be formed over PLL 199 using a sub-atmospheric chemical vapor deposition (SACVD) process using TEOS, wherein a deposition layer having a thickness of several thousands of nanometers may be initially formed that may be planarized in a chemical-mechanical polishing (CMP) process to have a total PMD stack thickness of about 150 nm to 250 nm or more depending on implementation.

A multi-stage CT etch process having stages with differential etch selectivities may be sequentially applied using appropriate etch chemistries in order to form contact apertures or holes through the PMD stack 122 and ESL 115. Although not specifically shown in the Figures, a photoresist may be applied over the PMD stack 122 of the semiconductor device 100 and patterned in a contact mask photolithography process for defining contact holes having suitable size(s) and dimension(s) relative to the fabrication of the semiconductor device 100. After the photoresist is patterned to expose specific locations over a top surface of the PMD stack 122 where contact holes are to be formed in reference to the contact areas/regions of the gate structure 105 and S/D regions 104A/104B, a first etch stage may be performed using a suitable etch recipe (e.g., a dry/plasma etch) as set forth in FIG. 1E and at block 208. In an example arrangement, the first stage etch (referred to herein as PMD oxide etch) is preferentially more selective to the PMD oxide layer 120 than to the nitride-based PLL 119, wherein the first stage etch is operable to remove the PMD oxide material more readily (e.g., at a higher rate) then the underlying nitride-based PLL material. Accordingly, the first etch stage is operable to stop on or land within the PLL 119 while removing the stack material to create one or more partially formed contact holes in alignment with the contact mask pattern. In one implementation, the first stage etch may comprise a recipe including a combination of gases, e.g., carbon tetrafluoride (CF₄), octafluorocyclopentene (C₅F₈), argon (Ar) and oxygen (O₂), etc., that may be applied using suitable gas flow ratios in a chamber having pressures in the millitorr range. In some arrangements, the first stage etch has a selectivity ratio greater than 2:1 as between the PMD oxide layer 120 and PLL 119, i.e., the first stage etch is operable to remove material from the PMD oxide layer 120 at an etch rate at least twice the rate of removal of material from PLL 119. Because PLL 119 is more resistant to the PMD oxide etch, PLL 119 may be considered a first (or initial) etch stop layer in some process flows. Depending on implementation, an example PMD oxide etch may be configured to remove PMD oxide material at rates around 200 nm to 250 nm per minute. As shown in FIG. 1E, reference numbers 124A/124B and 124C are illustrative of partially formed contact holes having different depths (e.g., D1 and D2) relative to the silicided S/D and gate contact regions/areas 103A/103B and 114, respectively.

Thereafter, a second etch stage (referred to herein as a PMD liner etch or PLL etch) may be performed for increasing the respective depths (e.g., to D1′ and D2′) of the partially formed contact holes as set forth in FIG. 1F and at block 210, whereby remaining material of PLL 119 may be removed using an etch recipe that is more preferential to the PMD liner material than to ESL 115. For example, the PMD liner etch may be operable to remove the PMD liner material at a rate at least twice the rate of removal of the ESL material (i.e., having an etch ratio of greater than 2:1). Accordingly, the second etch stage may be configured to stop on or land within ESL 115 while deepening the partially formed contact holes 124A-124C. In some arrangements, the second stage etch may also comprise a dry/plasma etch using a combination of gases similar to the gases set forth above for the first stage etch although the gas flow rate or ratios, power, pressure or bias may be different in order to achieve the desired relative selectivity as between the PMD liner material and the ESL material. In some examples, the second stage etch may be configured to remove the PLL nitride material at rates around 20 nm to 40 nm per minute.

In a third etch stage, partially formed contact holes 124A-124C may be deepened further to form completed contact holes (e.g., having depths D1″ and D2″) that land in the silicide areas of the respective contact regions/areas, as set forth in FIGS. 1G-1 and 1G-2 and at block 212. In some arrangements, the photoresist used to transfer the contact mask pattern may be removed by plasma ashing prior to the third etch stage in order to prevent the subsequent removal of PR material from creating undesirable debris in the contact hole and/or damaging or otherwise compromising the contacting silicide interface. Depending on implementation, the third etch stage (referred to herein as ESL etch) may comprise a wet or dry process using a recipe that is more preferentially selective to ESL 115 than to underlying material, which may include metal-silicide material, oxide material and/or diffusion area material depending on whether the contact holes are being formed in the silicided S/D contact regions 103A/103B or in the gate silicide 114. Where a dry process is implemented, a combination of gases similar to the gases used in the first and second etch stages set forth above may be used in appropriate gas flow ratios to achieve the desired relative selectivity (e.g., greater than 2:1) as between the ESL material and the underlying materials. Because the ESL etch stage of the present disclosure is more selective than baseline PMD liner etches that can etch away exposed oxide/silicon in the S/D contact regions more readily, the risks of overetching any exposed oxide regions adjacent to gate-to-contact spacings, e.g., regions 113A/B, as well as underlying doped substrate material may be advantageously minimized. Depending on how conservative the process optimization is, an ESL etch stage may be endpointed to leave a remaining portion of the exposed oxide areas 113A/113B, causing minimal concavity therein (also referred to as “dishing”), e.g., without punching through the exposed oxide material and without removing underlying silicon. In such a scenario, there may not be any overetch cavities formed in the underlying doped regions, as depicted in FIG. 1G-1, wherein a bottom 167 of the contact hole, e.g., contact hole 124B, may include an intact portion of the oxide area 113B (e.g., without perforations). In a more aggressive optimization scenario, an example EST etch stage may punch through the oxide material (ranging from partial removal or complete removal), thereby causing overetch cavities 199A, 199B in the underlying doped regions, as depicted in FIG. 1G-2. In one example partial removal scenario, the ESL etch stage may create one or more perforations in the exposed oxide region, thereby resulting in a bottom of the contact hole that includes at least a punched-through portion of the exposed oxide region. Depending on the severity of punch-through, overetch cavities 199A/199B may comprise lacunae having different sizes. However, such overetech cavities 199A/199B are expected to be smaller than overetch cavities resulting in a baseline process. It should be appreciated that smaller overetch regions 199A, 199B may reduce the risk of shorting due to any secondary silicidation that may be caused in a subsequent contact metallization process. Further, whereas overetch cavities are more prevalent (e.g., formed in greater numbers) in some example baseline processes, the described process herein significantly may reduce the number of overetch cavities or eliminate them altogether in some implementations.

Depending on etch process optimization, the semiconductor device 100 may therefore include a multi-layer vertical sidewall arrangement around the gate structure 105 because of the foregoing multi-stage CT etch process as illustrated in the fabrication stages of FIGS. 1G-1 and 1G-2. An example vertical sidewall arrangement 177 associated with gate structure 105 may comprise the oxide sidewall spacer 112A surrounded by a vertical portion 171 of ESL 115 remaining unconsumed after the ESL etch stage, which in turn may be at least partially surrounded by a PLL portion 173 that may remain unconsumed after the PLL etch stage. It should be appreciated that at least one or more of the vertical components of the sidewall arrangement 177 may have a tapered surface facing the contact hole (e.g., contact hole 124B) depending on the etch conditions of the respective stages of the CT etch process required for a desired contact hole taper profile. Although not strictly anisotropic, the respective stages of the CT etch process may therefore be configured with different etch rate selectivities so as to achieve various contact hole taper profiles, wherein the multi-layer sidewall arrangements surrounding the gates may comprise varying amounts of unconsumed PLL and ESL materials.

At block 214 and as set forth in FIG. 1H, a contact metallization process is illustrated, wherein suitable contact liners and plugs may be used to fill the completed contact holes (also referred to as openings, apertures, or other terms of similar import) for forming contact posts or plugs 150A-150C of the semiconductor device 100. For example, contact holes may be metallized using a titanium (Ti) and/or titanium nitride (TiN) liner followed by a tungsten (W) filler, although other metallurgies may be implemented in additional and/or alternative arrangements. Accordingly, after completion of contact metallization, example contact plugs 150A-150C are formed over the S/D regions 104A/104B and gate structure 105, respectively, wherein the contact plugs 150A-150C extend through a dielectric layer (e.g., PMD stack 122). With respect to the S/D regions 104A/104B, the contact plugs 150A/150B may extend through a first etch stop layer, e.g., PLL 119, and a second etch stop layer, e.g., ESL 115, and landing on a horizontal remaining portion of an oxide extension, e.g., where the ESL etch does not completely remove the exposed oxide areas 113A/113B. Where overetch cavities or regions are created in the doped S/D regions, e.g., overetch cavities 199A/199B shown in FIG. 1G-2, they may be filled/silicided in the metallization process, as represented by metallized extensions 197A/197B of the S/D silicides 108A/108B in FIG. 1H. For examples in which a portion of the exposed oxide areas 113A/113B remain (FIG. 1G-1), a portion of the contact plugs 150A/150B may land on such remaining portions, possibly resulting in slightly increased contact resistance for the contact plugs 150A/150B, but such an increase is expected to be negligible. In both examples, with and without remaining exposed oxide areas 113A/113B, the risks related to void formation in the S/D regions 104A, 104B is substantially reduced or eliminated. Furthermore, it should be appreciated that because the risk of extensive overetch during contact hole completion is substantially reduced in the ESL etch stage, more aggressive metallurgies and/or metallization processes may be implemented according to some examples, which may be particularly advantageous as the process nodes continue to scale to smaller geometries.

While various examples of the present disclosure have been described above, it should be understood that they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride.

Further, in at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

It should therefore be clearly understood that the order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure.

At least some portions of the foregoing description may include certain directional terminology, such as, e.g., “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged mutatis mutandis, depending on the context, implementation, etc. Further, the features of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” All structural and functional equivalents to the elements of the above-described implementations that are known to those of ordinary skill in the art are expressly incorporated herein by reference and are intended to be encompassed by the claims appended below.

What is claimed is:

1. A semiconductor device, comprising:
a source/drain region over a semiconductor substrate;
an oxide layer extension extending from the source/drain region toward a gate dielectric layer; and
a contact plug extending through a dielectric layer over the source/drain region, the contact plug extending through a first etch stop layer and a second etch stop layer to a horizontal remaining portion of the oxide layer extension.

2. The semiconductor device as recited in claim 1, wherein the second etch stop layer comprises at least one of silicon carbide nitride (SiCN), silicon oxynitride (SiON) and silicon carbide (SiC).

3. The semiconductor device as recited in claim 1, wherein the second etch stop layer has a thickness of about 5 nm to 10 nm.

4. The semiconductor device as recited in claim 1, wherein the second etch stop layer comprises a stressor film having a film stress greater than 1 Gigapascal (GPa).

5. The semiconductor device as recited in claim 4, wherein the source/drain region and a gate structure associated with the source/drain region are configured to operate as an NMOS transistor and the stressor film is operable as a tensile stressor.

6. The semiconductor device as recited in claim 4, wherein the source/drain region and a gate structure associated with the source/drain region are configured to operate as a PMOS transistor and the stressor film is operable as a compressive stressor.

7. A semiconductor device, comprising:
a substrate including a source region, a drain region and a channel region separating the source region and the drain region;
a gate dielectric layer over the channel region;
a gate structure over the gate dielectric layer; and
a contact opening over the source region or the drain region, the contact opening extending through an etch stop layer underlying a pre-metal dielectric (PMD) stack comprising a PMD liner overlying the etch stop layer and a PMD layer overlying the PMD liner.

8. The semiconductor device as recited in claim 7, wherein the gate structure is covered by a multi-layer vertical sidewall including an oxide layer, a portion of the etch stop layer at least partially covering the oxide layer, and a portion of the PMD liner at least partially covering the etch stop layer.

9. The semiconductor device as recited in claim 7, wherein the etch stop layer comprises at least one of silicon carbide nitride (SiCN), silicon oxynitride (SiON) and silicon carbide (SiC).

10. The semiconductor device as recited in claim 7, wherein the etch stop layer has a thickness of about 5 nm to 10 nm.

11. The semiconductor device as recited in claim 7, wherein a bottom of the contact opening includes an intact portion of an oxide layer extension extending from the gate dielectric layer toward the source region or the drain region.

12. The semiconductor device as recited in claim 7, wherein a bottom of the contact opening includes a punched-through portion of an oxide layer extension extending from the gate dielectric layer toward the source region or the drain region.

13. A method of fabricating a semiconductor device, the method comprising:
in a first etch stage for forming a contact hole in a contact region of the semiconductor device, etching an oxide layer of a pre-metal dielectric (PMD) stack to create a partially formed contact hole extending through the oxide layer and landing in a first etch stop layer forming part of the PMD stack;
in a second etch stage, etching the first etch stop layer to extend the partially formed contact hole to land in a second etch stop layer overlying a silicide area of the contact region, the silicide area abutting an oxide layer extension extending from a source/drain region toward a gate dielectric layer; and
in a third etch stage, etching the second etch stop layer to form a completed contact hole landing on the silicide area of the contact region and at least a portion of the oxide layer extension remaining unconsumed after the third etch stage.

14. The method as recited in claim 13, wherein the second etch stop layer comprises a conformal layer formed of a material selected from at least one of silicon carbide nitride (SiCN), silicon oxynitride (SiON) and silicon carbide (SIC).

15. The method as recited in claim 13, wherein the second etch stop layer has a thickness of about 5 nm to 10 nm and the PMD stack has a thickness of about 150 nm to 200 nm.

16. The method as recited in claim 13, wherein the second etch stop layer is formed as a stressor film having a film stress greater than 1 Gigapascal (GPa).

17. The method as recited in claim 13, wherein the at least a portion of the oxide layer extension remaining unconsumed after the third etch stage comprises a perforated portion.

18. The method as recited in claim 13, wherein the at least a portion of the oxide layer extension remaining unconsumed after the third etch stage comprises an intact portion.

19. The method as recited in claim 13, wherein the first etch stage is performed using an etch recipe having a selectivity ratio greater than 2:1.

20. The method as recited in claim 13, wherein the second etch stage is performed using an etch recipe having a selectivity ratio greater than 2:1.

21. The method as recited in claim 13, wherein the third etch stage is performed using an etch recipe having a selectivity ratio greater than 2:1.
